(19) United States
(12) Patent Application Publication
(10) Pub. No.: US 2023/0345682 A1
(43) Pub. Date: Oct. 26, 2023

(54) DISPLAY APPARATUS

(71) Applicant: SAMSUNG ELECTRONICS CO., LTD., Suwon-si (KR)

(72) Inventors: Hyeonyeon PARK, Suwon-si (KR); Hansol LEE, Suwon-si (KR); Yongyeon HWANG, Suwon-si (KR)

(73) Assignee: SAMSUNG ELECTRONICS CO., LTD., Suwon-si (KR)

(21) Appl. No.: 18/216,053

(22) Filed: Jun. 29, 2023

Related U.S. Application Data
(63) Continuation of application No. PCT/KR2021/018838, filed on Dec. 13, 2021.

(30) Foreign Application Priority Data
Jan. 29, 2021 (KR) 10-2021-0013453

(51) Int. Cl. H05K 7/20; H05K 1/02

(52) U.S. Cl. CPC H05K 7/20972; H05K 1/021; G02B 6/0085

(57) ABSTRACT

A display apparatus comprises: a display panel on which a screen is displayable along a first direction; a light source module including a plurality of light sources, spaced apart from each other along a second direction perpendicular to the first direction 1; a rear chassis including a plurality of coupling protrusions spaced apart from each other along the second direction; and a heat dissipation member includes a plurality of insertion holes, into which the plurality of coupling protrusions of the rear chassis are insertable, spaced apart from each other along a long axis of the heat dissipation member which extends along the second direction, and among the plurality of insertion holes, a first insertion hole at a center along the long axis and a second insertion hole adjacent to a side end of the heat dissipation member along the long axis in a shape elongated along the long axis.

### CROSS-REFERENCE TO RELATED APPLICATION

This application is a continuation application, under 35 U.S.C. §111(a), of international application No. PCT/KR2021/018838, filed on Dec. 13, 2021, which claims priority under 35 U. S. C. §119 to Korean Patent Application No. 10-2021-0013453, filed Jan. 29, 2021, the disclosures of which are incorporated herein by reference in their entireties.

### BACKGROUND

### Field

The present disclosure relates to a display apparatus, and more specifically, to a display apparatus including a coupling structure of a heat dissipation configuration.

### Description of Related Art

In general, a display apparatus is an apparatus that displays a screen, and includes a monitor or a television. For the display apparatus, a self-emissive display panel, such as an organic light-emitting diode (OLED) and a non-emissive display panel, such as a liquid crystal display (LCD) panel are used.

The disclosure relates generally to a display module and a display apparatus, to which a non-emissive display panel is applied. A display apparatus, to which a non-emissive display panel is applied, includes a display panel formed of a liquid crystal panel and on which a screen is displayed, and a backlight unit for supplying light to the liquid crystal panel, in which the backlight unit includes a light source module having a light source, a light guide plate for receiving light from the light source and exiting light to the display panel, and a plurality of optical sheets allowing the light passed through the light guide plate to pass therethrough. In this case, the optical sheets may include a reflective sheet, a light guide plate or a diffusion sheet, and a prism sheet, a diffusion sheet, a polarizing sheet, and the like.

Reliability of the display apparatus may be degraded due to heat generated from the light source module of the backlight unit, and to prevent this, the light source module may include a heat dissipation member for dissipating heat of the light source.

### SUMMARY

Embodiments of the disclosure provides a display apparatus including: a display panel on which a screen is displayable along a first direction; a light source module, including a plurality of light sources configured to emit light toward the display panel, the plurality of light sources being spaced apart from each other along a second direction perpendicular to the first direction; a rear chassis to support the light source module, which is arrangeable at a rear side of the display panel, the rear chassis including a plurality of coupling protrusions spaced apart from each other along the second direction; and a heat dissipation member coupleable to the rear chassis and configured to dissipate heat generated from the light source module, the heat dissipation member including a plurality of insertion holes into which the plurality of coupling protrusions of the rear chassis are insertable, the plurality of insertion holes being spaced apart from each other along a long axis of the heat dissipation member which extends along the second direction, a first insertion hole, among the plurality of insertion holes, is at a center along the long axis and a second insertion hole, among the plurality of insertion holes, is adjacent to a side end of the heat dissipation member along the long axis, and in a shape elongated along the long axis.

The heat dissipation member may be formed of a material having greater thermal expansion than the rear chassis.

A first coupling protrusion, among the plurality of coupling protrusions, is insertable into the first insertion hole and a second coupling protrusion, among the plurality of coupling protrusions, is insertable into the second insertion hole, and a width of the second coupling protrusion along the second direction may be smaller than a width of the second insertion hole along the second direction.

The second coupling protrusion while inserted in the second insertion hole, may be configured to be movable along the second direction within the second insertion hole.

A first coupling protrusion, among the plurality of coupling protrusions, is insertable into the first insertion hole and a second coupling protrusion, among the plurality of coupling protrusions, is insertable into the second insertion hole, and the second coupling protrusion may be formed in a hook shape bent along a third direction perpendicular to the first direction and the second direction.

The second coupling protrusion may include a bent portion at which the second coupling protrusion extending along the first direction may be bent toward the third direction and an end portion extending along the third direction from the bent portion, and the end portion may be disposed outside the second insertion hole along the third direction.

An area between a base of the second coupling protrusion and the bent portion in the first direction may be configured not to be in contact with the heat dissipation member.

The end portion of the display apparatus may be configured to be in contact with the heat dissipation member.

A first coupling protrusion, among the plurality of coupling protrusions, is insertable into the first insertion hole and a second coupling protrusion, among the plurality of coupling protrusions, is insertable into the second insertion hole, and the first coupling protrusion may be configured to be supported on the first insertion hole without a gap.

A first coupling protrusion, among the plurality of coupling protrusions, is insertable into the first insertion hole and a second coupling protrusion, among the plurality of coupling protrusions, is insertable into the second insertion hole, and the first coupling protrusion may be in a tubular shape protruding in the first direction, and an end portion of the first coupling protrusion along the first direction may be bent to face toward the heat dissipation member.

The end portion of the first coupling protrusion may be bent along a third direction perpendicular to the first direction and the second direction to be in contact with the heat dissipation member.

A first coupling protrusion, among the plurality of coupling protrusions, is insertable into the first insertion hole and a second coupling protrusion, among the plurality of coupling protrusions, is insertable into the second insertion hole, the first coupling protrusion may be in a tubular shape protruding along the first direction, and an end portion of the first coupling protrusion along the first direction may be configured to be in contact with the heat dissipation member.

A first coupling protrusion, among the plurality of coupling protrusions, is insertable into the first insertion hole and a second coupling protrusion, among the plurality of coupling protrusions, is insertable into the second insertion hole, and the first coupling protrusion may be configured to be insertable into the first insertion hole without a gap.

A first coupling protrusion, among the plurality of coupling protrusions, is insertable into the first insertion hole and a second coupling protrusion, among the plurality of coupling protrusions, is insertable into the second insertion hole, and the first coupling protrusion may be configured to be fixed to the first insertion hole, and the second coupling protrusion may be supported to be movable along the second direction inside the second insertion hole.

The first insertion hole and the second insertion hole may each be is among a plurality of first insertion holes, and a number of the plurality of first insertion holes may be greater than a number of the plurality of second insertion holes.

In addition, the first insertion hole may include an inner wall that forms the first insertion hole and extends to slope with respect to the first direction, and the second insertion hole includes an inner wall that forms the second insertion hole and extends in parallel with the first direction.

Embodiments of the disclosure provides a display apparatus including: a display panel on which a screen is displayable along a first direction; a light source module including a plurality of light sources configured to emit light to the display panel and spaced apart from each other along a second direction perpendicular to the first direction; a rear chassis, to support the light source module, which is arrangeable at a rear side of the display panel; and a heat dissipation member coupleable to the rear chassis and configured to dissipate heat generated from the light source module, wherein the rear chassis includes a plurality of coupling protrusions configured to be inserted into the heat dissipation member and spaced apart from each other in the second direction, the heat dissipation member includes a long axis extending along the second direction and a plurality of insertion holes, into which the plurality of coupling protrusions are inserted, spaced apart from each other along a direction of the long axis, the plurality of insertion holes include a first insertion hole at a center in an extension direction of the long axis and a second insertion hole adjacent to a side end of the heat dissipation member along the direction of the long axis, where a first coupling protrusion, among the plurality of coupling protrusions is insertable, into the first insertion hole and a second coupling protrusion, among the plurality of coupling protrusions is insertable, into the second insertion hole, and the first coupling protrusion is configured to be fixed to the first insertion hole, and the second coupling protrusion is supported to be movable in the second direction inside the second insertion hole.

The second insertion hole may be formed in a long hole shape having a length along the extension direction of the long axis.

A width of the second coupling protrusion in the second direction may be smaller than a width of the second insertion hole in the second direction.

The second coupling protrusion may be configured to be movable in the second direction within the second insertion hole.

The first coupling protrusion may be configured to be supported on the first insertion hole without a gap.

### BRIEF DESCRIPTION OF THE DRAWINGS

These and/or other aspects of the disclosure will become apparent and more readily appreciated from the following description of embodiments, taken in conjunction with the accompanying drawings of which:

FIG. 1 is a perspective view illustrating a display apparatus according to an embodiment of the present disclosure.

FIG. 2 is an exploded perspective view illustrating a display apparatus according to an embodiment of the present disclosure.

FIG. 3 is a partial cross-sectional view of a display apparatus according to an embodiment of the present disclosure.

FIG. 4 illustrates a front view of some components and an enlarged front view of some components of a display apparatus according to an embodiment of the present disclosure.

FIG. 5 is a front view of a portion of a heat dissipation member of a display apparatus according to an embodiment of the present disclosure.

FIG. 6 is a front view of a portion of a rear chassis of a display apparatus according to an embodiment of the present disclosure.

FIG. 7 is a cross-sectional view of part A of FIG. 4 according to an embodiment of the present disclosure.

FIG. 8 is a cross-sectional view of part B of FIG. 4 according to an embodiment of the present disclosure.

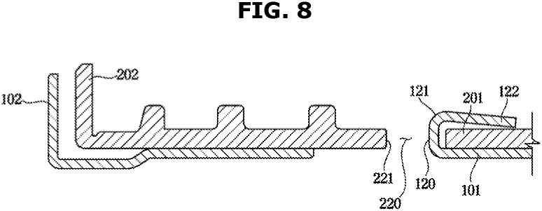

FIG. 9 is a view illustrating a coupling operation of a first coupling protrusion of a rear chassis of a display apparatus according to an embodiment of the present disclosure.

FIG. 10 is a view illustrating a coupling operation of a first coupling protrusion of a rear chassis of a display apparatus according to an embodiment of the present disclosure.

FIG. 11 is a view illustrating a coupling operation of a second coupling protrusion of a rear chassis of a display apparatus according to an embodiment of the present disclosure.

FIG. 12 is a view illustrating a coupling operation of a second coupling protrusion of a rear chassis of a display apparatus according to an embodiment of the present disclosure.

### DETAILED DESCRIPTION

The embodiments described in the present specification and the configurations shown in the drawings are only examples of preferred embodiments of the present disclosure, and various modifications may be made at the time of filing of the present disclosure to replace the embodiments and drawings of the present specification.

Further, identical symbols or numbers in the drawings of the present disclosure denote components or elements configured to perform substantially identical functions.

Further, terms used herein are only for the purpose of describing particular embodiments and are not intended to limit to the present disclosure. The singular form is intended to include the plural form as well, unless the context clearly indicates otherwise. It should be further understood that the terms “include,” “including,” “have,” and/or “having” specify the presence of stated features, integers, steps, operations, elements, components, and/or groups thereof, but do not preclude the presence or addition of one or more other features, integers, steps, operations, elements, components, and/or groups thereof.

Further, it should be understood that, although the terms “first,” “second,” etc. may be used herein to describe various elements, the elements are not limited by the terms, and the terms are only used to distinguish one element from another. For example, a first element could be termed a second element, and similarly, a second element could be termed a first element without departing from the scope of the present disclosure. The term “and/or” includes combinations of one or all of a plurality of associated listed items.

One aspect of the present disclosure provides a display apparatus in which a rear chassis coupled to a heat dissipation member of a light source module is provided with a structure that compensates for a separation between each component caused by thermal expansion.

The display apparatus according to an embodiment of the present disclosure is implemented to, while a heat dissipation member of a light source module and a rear chassis formed of a different material from the heat dissipation member are coupled to each other, prevent noise due to each component having different dimensions of thermal deformation during thermal expansion by including a slit in a longitudinal direction of the heat dissipation member in at least a part of a coupling portion, in which the heat dissipation member is coupled to the rear chassis, to compensate for a separation caused by thermal deformation, so that the heat dissipation member and the rear chassis can maintain a stable coupling even when each component is thermally expanded.

Hereinafter, an embodiment according to the disclosure will be described in detail with reference to the accompanying drawings.

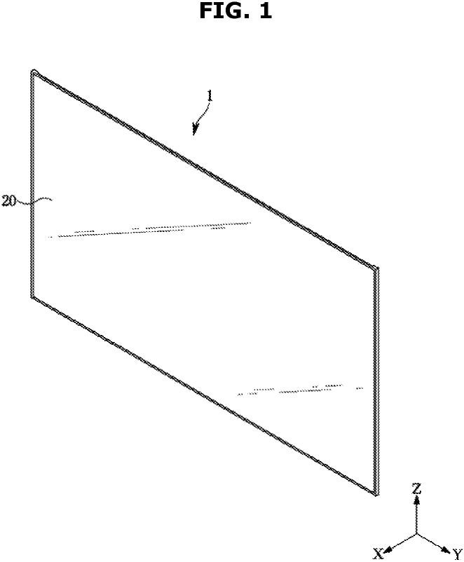

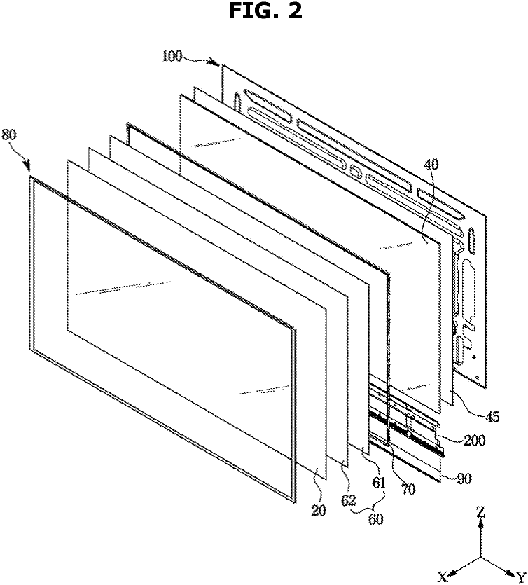

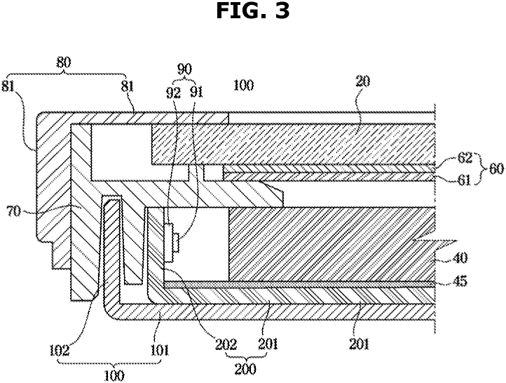

FIG. 1 is a perspective view illustrating a display apparatus according to an embodiment of the present disclosure, FIG. 2 is an exploded perspective view illustrating a display apparatus according to an embodiment of the present disclosure, and FIG. 3 is a partial cross-sectional view of a display apparatus according to an embodiment of the present disclosure;

Although the disclosure is described in relation to a flat display apparatus 1 as an example, it is also applicable to a curved display apparatus or a bendable display apparatus.

The display apparatus 1 includes a display module for displaying an image therein.

The display module includes a display panel 20, on which an image is displayed, and a backlight unit for supplying light to the display panel 20. The backlight unit may include a light source module 90 and an optical sheet 60 which includes a first sheet member 61 and a second sheet member 62. The backlight unit may include the light source module 90 disposed behind the display panel 20, a light guide plate 40 disposed in a space between the display panel 20 and the light source module 90 for the light from the rear side to be diffused and thus transmitted to the display panel 20 positioned on the front side, an optical sheet 60 disposed between the light guide plate 40 and the display panel 20 to change optical properties, a middle mold 70 supporting the display panel 20 and the light guide plate 40, and display chassis 80 and 100 forming the external appearance. The display chassis 80 and 100 includes a front chassis 80 coupled to a front side of the middle mold 70 for the display panel 20 to be kept installed in the middle mold 70 and a rear chassis 100 coupled to a rear side of the middle mold 70 and allowing above-described light source modules 30 to be disposed on both inner sides thereof.

The light source module 90 may be coupled to a front side of the rear chassis 100 to transmit light toward the center of the rear chassis 100. In the embodiment of the disclosure, the light source 30 is disposed at a lower side of the display module, but is not limited thereto, and the light source may be applied to only at least one of a lower side, a lateral side, or an upper side of the display module, and may be applied to all sides along the periphery of the display module. The light source may be applied in such an edge type display, or in a direct type display.

In the middle mold 70, the light guide plate 40, the display panel 20, and the front chassis 80 may be sequentially installed on the front side thereof, and the rear chassis 100 is installed on the rear side thereof to support the respective components while allowing the display panel 20 and the rear chassis 100 to be kept apart from each other.

The front chassis 80 includes a bezel portion 81 that covers an external peripheral side of a front surface of the display panel 20, and a front side surface portion 82 that is bent at an end portion of the bezel portion 81 toward the rear side to cover a side surface of the middle mold 70.

The rear chassis 100 may include a surface portion 101 forming the rear side of the display module while facing the display panel 20, and a rear side portion 102 extending forward from the circumference of the surface portion 101 and coupled to the middle mold 70.

The light source module 90 may include a light source package 91 and a printed circuit board 92.

The light source package 91 may include a light source The light source includes a light emitting device (a light emitting diode: LED). The light source package 91 may be provided in a plurality of units thereof. The plurality of light source packages 91 may be disposed to be spaced apart from each other on the printed circuit board 92.

In detail, the plurality of light source packages 91 may be arranged spaced apart from each other in the left-right directions Y. In addition, the printed circuit board 92 maty be provided to have a longitudinal direction extending in the left-right direction Y, and the plurality of light source packages 91 may be spaced apart from each other on the printed circuit board 92 extending in the left-right direction Y.

The light source 90 may include a blue light emitting device as a light source, and may additionally include a. light conversion member. The light conversion member may be packaged by the light source package 91 or installed in the light source module 90 as a different component.

The light conversion member 130 is disposed between the light source and the light guide plate 40 to change the wavelength of light transmitted from the light source to the light guide plate 40. The light conversion member is provided to convert properties of light generated from the light source and directed toward the light guide plate 40. In detail, the light conversion member is configured to convert a wavelength of light. The light conversion member may include a quantum dot (QD).

However, unlike the embodiment of the present disclosure, the light conversion member may not be included in the light source module 90, and may be disposed between the light guide plate 40 and the display panel 20 or between the light source package 91 and the light guide plate 40 as a separate component.

The light guide plate 40 may include a reflective member 45 formed on a rear surface thereof. The reflective member 45 may be provided on the rear surface of the light guide plate 40 so that all of the light generated from the light source is directed to the front. The reflective member 45 may be a reflective plate configured separately from the light guide plate 40 and disposed on the rear surface of the light guide plate 40, or may be integrally formed with the light guide plate 40. In addition, the same effect as the above may be provided by forming a reflective coating on the rear surface of the light guide plate 40.

The light guide plate 40 is provided to transmit light generated from the light source. To this end, the light guide plate 40 may be formed of a transparent resin material. In order to minimize deformation due to heat generated from the light source, the light guide plate 40 may be disposed to be spaced apart from the light source by a predetermined distance.

The display apparatus 1 may include a heat dissipation member 200 to dissipate heat generated from the light source module 90.

The heat dissipation member 200 is configured to dissipate heat generated from the plurality of light source packages 91. Heat generated from the light source is configured to be transmitted through the light source package 91 and the printed circuit board 92 to the heat dissipation member 200, so that the heat emitted from the light source package 91 is dissipated.

The heat dissipation member 200 may be provided to be coupled to the rear chassis 100. The heat dissipation member 200 may transfer heat generated from the light source module 90 to the rear chassis 100 to improve heat dissipation performance of the display apparatus 1.

The heat dissipation member 200 may include a plate portion 201 coupled to the surface portion 101 of the rear chassis 100 and a seating portion 202 bent from the plate portion 201 and on which the light source module 90 is seated.

The heat dissipation member 200 may be coupled to the rear chassis 100 such that the plate portion 201 substantially faces the surface portion 101 of the rear chassis 100 and the seating portion 202 is directed upward on a front side of the surface portion 101.

Accordingly, the light source of the light source module 90 may be disposed to face upward in the upper-lower direction Z. The light source module 90 may be provided to be in contact with the seating portion 202. In detail, the printed circuit board 92 may be supported while in contact with the seating portion 202. Preferably, the entire area of the printed circuit board 92 in the longitudinal direction Y may be provided to be in contact with the seating portion 202.

As the seating portion 202 of the heat dissipation member 200 is contact with the light source module 90, heat generated from the light source module 90 may be efficiently transferred to the heat dissipation member 200, and the heat transferred to the heat dissipation member 200 may be efficiently transferred to the rear chassis 100 coupled to the heat dissipation member 200 so that the heat dissipation of the display apparatus 1may be efficiently performed.

As described above, since the printed circuit board 91 extends in the left-right direction Y, the heat dissipation member 200 may extend in the left-right direction Y and have the left-right direction Y as a longitudinal direction.

That is, the heat dissipation member 200 may be provided in a rectangular plate shape extending substantially in the left-right direction Y and bent at a lower side.

Hereinafter, a coupling configuration between the heat dissipation member 200 and the rear chassis 100 will be described in detail.

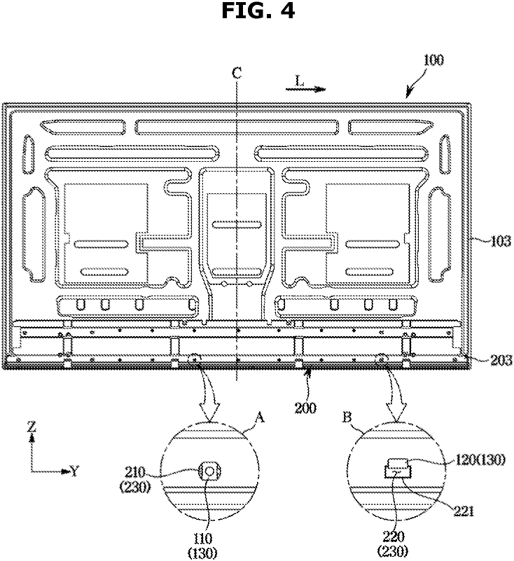

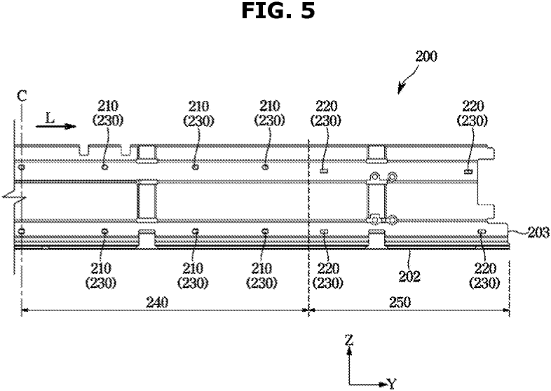

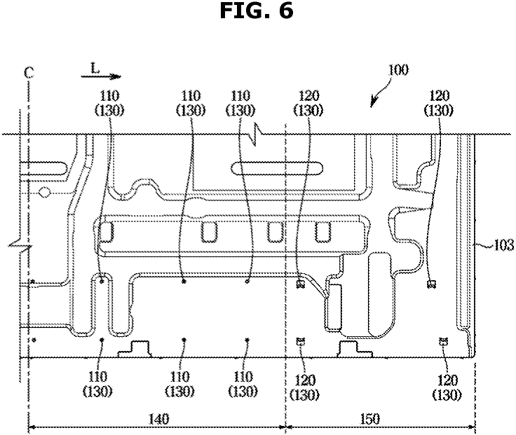

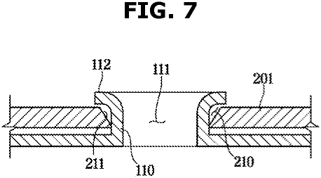

FIG. 4 illustrates a front view of some components and an enlarged front view of some components of a display apparatus according to an embodiment of the present disclosure, FIG. 5 is a front view of a portion of a heat dissipation member of a display apparatus according to an embodiment of the present disclosure, FIG. 6 is a front view of a portion of a rear chassis of a display apparatus according to an embodiment of the present disclosure, and FIG. 7 is a cross-sectional view of part A of FIG. 4.

As described above, the rear chassis 100 may be connected to the heat dissipation member 200 to dissipate heat generated from the light source module 90 and heat generated from the display module 20 and the like. However, the rear chassis 100 may be formed of a material with high strength to secure rigidity of the display apparatus 1 as well as heat dissipation. Preferably, the rear chassis 100 may be formed of a steel plate formed of a steel material.

The heat dissipation member 200 is desirable to secure a certain level of rigidity as a component to support the light source module 90, but may be formed of a material having high thermal conductivity as a component to dissipate heat generated from the light source module 90.The heat dissipation member 200 may be formed of a metal material having high thermal conductivity such as aluminum.

As described above, the rear chassis 100 and the heat dissipation member 200 may be formed of different materials due to having different main roles.

As described above, the rear chassis 100 and the heat dissipation member 200 are disposed in a state of being coupled to each other, but as the rear chassis 100 and the heat dissipation member 200 formed of different materials are coupled, the display apparatus 1 have a reliability issue.

In detail, when heat is transferred to each component, t the difference in the amount of thermal expansion of the materials forming each component may cause each component to change in size at different rates.

The heat dissipation member 200 may transfer the heat generated from the light source module 90 to the rear chassis 100, and accordingly, the heat dissipation member 200 and the rear chassis 100 may be thermally expanded by the heat stored in each component. In this case, the heat dissipation member 200 and the rear chassis 100 formed of different materials are expanded in different sizes, and when a coupling portion at which the rear chassis 100 and the heat dissipation member 200 are coupled to each other is supplied with a force greater than the stress of the coupling portion, a reliability issue occurs in the coupling portion.

In the display apparatus 1 according to an embodiment of the present disclosure, even when the rear chassis 100 and the heat dissipation member 200 are thermally expanded in different sizes, the components may be stably coupled to each other.

In detail, the rear chassis 100 includes a plurality of coupling protrusions 130 provided to be inserted into the heat dissipation member 200 and arranged spaced apart in the left-right direction Y, and the heat dissipation member 200 may include a plurality of insertion holes 230 arranged spaced apart in the left-right direction Y and into which the plurality of coupling protrusions 130 are inserted.

The plurality of coupling protrusions 130 of the rear chassis 100 are coupled to the plurality of insertion holes 230 of the heat dissipation member 200 in the front-rear direction X so that the rear chassis 100 and the heat dissipation member 200 are coupled to each other.

The plurality of insertion holes 230 include a first insertion hole 210 disposed at a center portion in the left-right direction Y and a second insertion hole 220 disposed adjacent to both side ends of the heat dissipation member 200 in the left-right direction Y.

Each of the first insertion hole 210 and the second insertion hole 220 may be provided in a single unit, but may preferably be provided in a plurality of units thereof. Each of the first insertion hole 210 and the second insertion hole 220 of the heat dissipation member 200 of the display apparatus 1 according to an embodiment of the present disclosure may be provided in plural.

In addition, the plurality of coupling protrusions 130 may include a first coupling protrusion 110 inserted into the first insertion hole 210 and a second coupling protrusion 120 inserted into the second insertion hole 220. Each of the coupling protrusions 110 and 120 may be provided in a shape protruding forward X from the surface portion 101. The first coupling protrusions 110 and the second coupling protrusions 120 may be provided corresponding in number to the numbers of the first insertion holes 210 and the second insertion holes 220, respectively.

However, hereinafter, for the sake of convenience of description, a single first insertion hole 210, a single second insertion hole 220, a single first coupling protrusion 110, and a single second coupling protrusion 120 are described as an example.

As described above, a difference in thermal expansion between the rear chassis 100 and the heat dissipation member 200 may lead to a degradation in the reliability of each coupling. That is, a portion in which the rear chassis 100 and the heat radiating member 200 are coupled is supplied with an external force generated by a difference in the deformation sizes of each component, and when the external force is greater than the stress on the portion in which the rear chassis 100 and the heat dissipation member 200 are coupled to each other, the reliability of the coupling may be lowered.

The heat dissipation member 200 is provided in a rectangular shape extending in the left-right direction Y, and has a thermal deformation that increases from the center C of the heat dissipation member 200 toward the side ends 203 of the heat dissipation member 200 in the left-right direction Y. The deformation values due to heat is accumulated from the center C in the left-right direction Y in the longitudinal direction L of the heat dissipation member 200, resulting in a largest deformation value at the side ends 203 of the heat dissipation member 200.

Accordingly, when compared with the first insertion hole 210 and the first coupling protrusion 110 disposed at the center in the left-right direction Y, the second insertion hole 220 and the second coupling protrusion 120 disposed adjacent to the side ends 203 are supplied with a greater external force and the coupling reliability of the second insertion hole 220 and the second coupling protrusion 120

On the other hand, in a central region C of the heat dissipation member 200 and the rear chassis 100, a deformation value due to thermal expansion is formed to a negligible extent, so that an external force transmitted to the first insertion hole 210 and the first coupling protrusion 110 is very small. Accordingly, there is no degradation in a coupling force between the first insertion hob 210 and the first coupling protrusion 110.

In addition, in the upper-lower direction Z forming a short side with respect to the left-right direction Y, which is the longitudinal direction L of the heat dissipation member 200, the length of the heat dissipation member 200 is formed short, so that the variance of external forces according to the difference in length is negligible. Accordingly, even when the plurality of coupling protrusions 130 are arranged to be spaced from the plurality of insertion holes 230 in a direction perpendicular to the longitudinal direction L of the heat dissipation member 200, the magnitudes of the external forces transmitted to each coupling protrusions 130 and insertion holes 230 may be formed approximately constant.

Accordingly, the second insertion hole 220 disposed adjacent to the side end 203 of the heat dissipation member 200 in the longitudinal direction L of the heat dissipation member 200 and the second coupling protrusion 120 disposed at a position corresponding to the second insertion hole 220 to be inserted into the second insertion hole 220 need to maintain efficient coupling even when there is a difference in thermal expansion sizes in the rear chassis 100 and the heat dissipation member 200.

To this end, the second insertion hole 220 may be provided in a long hole shape having a length 221 in the longitudinal direction L of the heat dissipation member 200.

As described above, the difference between the thermal expansion values of the rear chassis 100 and the heat dissipation member 200 is the largest in the longitudinal direction L of the heat dissipation member 200, and when the difference in size deformation generates an external force, the coupling between the second insertion hole 220 and the second coupling protrusion 120 may be disengaged, or the external force may be transmitted to the second insertion hole 220 or the second coupling protrusion 120 in the left-right directions L.

In this case, since the second insertion hole 220 is provided in the shape of a long hole having a length 221 in the longitudinal direction L, even when an external force is exerted on the coupling protrusion 120 in the longitudinal direction L, the second coupling protrusion 120 is partially movable in the longitudinal direction L in the second insertion hole 220, thereby preventing the second coupling protrusion 120 from being disengaged from the second insertion hole 220, or preventing an external force from being generated on the second coupling protrusion 120 or the second insertion hole 220.

The width of the second coupling protrusion 120 in the longitudinal direction L may be smaller than the width of the second insertion hole 220 in the longitudinal direction L. Accordingly, when an external force is generated, the second coupling protrusion 120 may be provided to be movable in the longitudinal direction L within the second insertion hole 220.

As described above, an external force due to a thermal deformation difference between the rear chassis 100 and the heat dissipation member 200 is formed to a small extent in the first insertion hole 210 and the first coupling protrusion 110. Accordingly, the first coupling protrusion 110 may be provided to be inserted into the first insertion hole 210 without a gap in the longitudinal direction L of the heat dissipation member 200.

The first coupling protrusion 110 may be inserted into the first insertion hole 210 without a gap not only in the longitudinal direction L but also in the upper-lower direction Z perpendicular thereto. This is because the difference in thermal deformation between the rear chassis 100 and the heat dissipation member 200 is insignificant in the area in which the first coupling protrusion 110 and the first insertion hole 210 are disposed.

As described above, the second coupling protrusion 220 and the second insertion hole 220 have a predetermined gap therebetween in the longitudinal direction L, which may result in a decrease in coupling strength to some degree, but due to the first coupling protrusion 110 inserted into the first insertion hole 210, the coupling strength between the rear chassis 100 and the heat dissipation member 200 may be increased.

That is, the first coupling protrusion 110 may be provided to be fixed to the first insertion hole 210 without a gap, and the second coupling protrusion 120 may be supported to be movable in the longitudinal direction L in the second insertion hole 220.

As for areas between the center C and the both side ends 203 in the longitudinal direction L of the heat dissipation member 200, an area closer to the center C is assumed as a first area 240 and an area closer to each side end 203 is assumed as a second area 250, and the first insertion hole 210 may be disposed on the first area 240 and the second insertion hole 230 may be disposed on the second area 250.

The criterion for dividing the first area 240 and the second area 250 in the longitudinal direction L may be set such that the second area 250 occupies 30% to 40% of the total length of the heat dissipation member 200 in the length direction L. Accordingly, the first area 240 may be provided with a wider area than the second area 250 in the longitudinal direction L.

In addition, the plurality of first insertion holes 210 disposed in the first area 240 may be provided in a greater number than the plurality of second insertion holes 220 disposed in the second area 250.

As the number of the first insertion holes 210 is greater than the number of the second insertion holes 220, the rear chassis 100 and the heat dissipation member 200 may be stably coupled.

As for areas between the center C and the both side ends 103 in the longitudinal direction L of the rear chassis 100, an area closer to the center C is assumed as a first area 140 and an area closer to each side end 103 is assumed as a second area 150, and the first coupling protrusion 110 may be disposed on the first area 140 and the second coupling protrusion 130 may be disposed on the second area 150.

The first area 140 and the second area 140 and 150 of the rear chassis 100 may be formed at positions corresponding to the first area 240 and the second area 250 of the heat dissipation member 200 in the front-rear direction X, respectively. Accordingly, the first area 140 of the rear chassis 100 may be larger than the second area 150.

In addition, since the first coupling protrusion 110 and the second coupling protrusion 120 are provided to correspond to the first insertion hole 210 and the second insertion hole 220, respectively, the first coupling protrusions 110 may be provided in a greater number than the second coupling protrusions 120.

The first coupling protrusion 0110 may be provided in a tubular shape protruding in the forward direction X. The first coupling protrusion 110 has a tubular shape having a hollow 111, and an end portion 112 of the first coupling protrusion 110 in the forward direction X may be provided to be bent.

In detail, the end portion 112 of the first coupling protrusion 110 may be provided to be bent to extend in the upper-lower direction Z or in the left-right direction Y.

Depending on the extent to which the end portion 112 of the first coupling protrusion 110 is bent, the portion end 112 may be disposed to be in contact with the plate portion 201 of the heat dissipation member 200.

Accordingly, the first coupling protrusion 110 may be fixed to the first insertion hole 210.

An inner wall 211 of the first insertion hole 210 forming the first insertion hole 210 may be formed to slope with respect to the front-back direction X.

The end portion 112 of the first coupling protrusion 110 is not limited to any one form, and may be bent to make contact with the inner wall 211 of the first insertion hole 210 or may be disposed outside the first insertion hole 210, or may be provided to extend to the outside of the first insertion hole 210 and make contact with the plate portion 201.

The second coupling protrusion 120 may be provided in a hook shape bent in the upper-lower direction Z.

In detail, the second coupling protrusion 120 may include a bent portion 121 at which the second coupling protrusion 120 formed in the front-back direction X is bent in the upper-lower direction Z and an end portion 122 extending in the upper-lower direction Z from the bent portion 121.

The end portion 122 of the second coupling protrusion 120 may be disposed outside the second insertion hole 220 in the upper-lower direction Z due to the bent portion 121.

An area between a base of the second coupling protrusion 120 and the bent portion 121 in the front direction X may be provided so as not to come into contact with the heat dissipation member 200. With such a configuration, even when a length deformation occurs due to a difference in thermal expansion between the rear chassis 100 and the heat dissipation member 200, an external force is not transmitted to the second coupling protrusion 120 and the second insertion hole 220.

That is, with the rear chassis 100 formed of steel, and the heat dissipation member 200 formed of aluminum, the heat dissipation member 200 has a high coefficient of thermal expansion, so that when heat is transferred, the heat dissipation member 200 may elongate more than the rear chassis 100 in the longitudinal direction L. Accordingly, the second insertion hole 220 is moved in the longitudinal direction L, and caused to collide with the second coupling protrusion 120 of the rear chassis 100, which has a smaller movement amount than the second insertion hole 220, generating an external force.

However, the area between the base of the second coupling protrusion 120 and the bent portion 121 in the front X is provided not to come into contact with the heat dissipation member 200, so that even when the second insertion hole 220 is deformed more than the second coupling protrusion 120 in the longitudinal direction L, the second insertion hole 220 and the second coupling protrusions 120 may not collide with each other, allowing the second coupling protrusions 120 to remain stably inserted into the second insertion holes 220.

An inner wall 221 of the second insertion hole 220 forming the second insertion hole 220 may be formed in parallel with the front-back direction X. This is to minimize collision with the second insertion hole 200 when the second coupling protrusion 120 is moved by thermal expansion.

On the other hand, the end portion 122 of the second coupling protrusion 120 may be provided to be in contact with the plate portion 201 of the heat dissipation member 200. Accordingly, coupling between the rear chassis 100 and the heat dissipation member 200 may be improved.

Hereinafter, a coupling operation between the heat dissipation member 200 and the rear chassis 100 will be described.

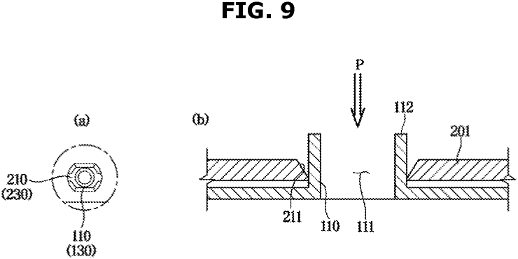

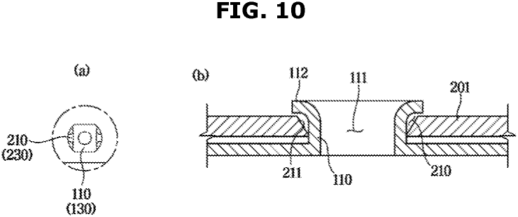

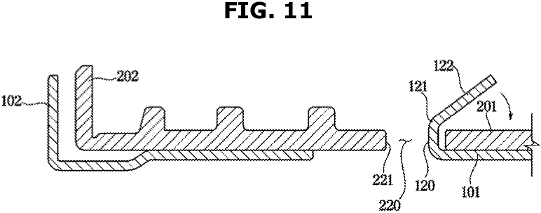

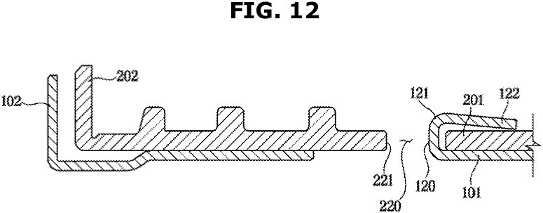

FIG. 9 is a view illustrating a coupling operation of a first coupling protrusion of a rear chassis of a display apparatus according to an embodiment of the present disclosure, FIG. 10 is a view illustrating a coupling operation of a first coupling protrusion of a rear chassis of a display apparatus according to an embodiment of the present disclosure, FIG. 11 is a view illustrating a coupling operation of a second coupling protrusion of a rear chassis of a display apparatus according to an embodiment of the present disclosure, and FIG. 12 is a view illustrating a coupling operation of a second coupling protrusion of a rear chassis of a display apparatus according to an embodiment of the present disclosure.

Referring to FIG. 9, the first coupling protrusion 110 may be provided in a tubular shape protruding in the forward direction X, and the end portion 112 of the first coupling protrusion 110 may be arranged in the forward direction X before the coupling of the rear chassis 100 and the heat dissipation member 200 is terminated.

After the first coupling protrusion 110 is inserted forward into the first insertion hole 210, the first coupling protrusion 110 may be subjected to press working (P), so that the end portion 112 may be compressed in the upper-lower direction Z or left-right direction Y.

Accordingly, the end portion 111 facing in the forward direction X may be provided to be bent in the upper-lower direction Z or in the left-right direction Y as shown in FIG. 10.

Since the first coupling protrusion 110 may not be inserted into the first insertion hole 210 while the end portion 111 of the first coupling protrusion 110 is in a state of being bent in the upper-lower direction Z or in the left-right direction Y, the first coupling protrusion 110 is inserted into the first insertion hole 210, and then the end portion 111 is bent through press working (P) to improve the coupling force between the rear chassis 100 and the heat dissipation member 200.

Referring to FIG. 11, the second coupling protrusion 120 may be provided in a plate shape protruding in the forward direction X, and the end portion 122 of the second coupling protrusion 120 may be arranged in the forward direction X before the coupling of the rear chassis 100 and the heat dissipation member 200 is terminated.

After the second coupling protrusion 120 is inserted forward into the second insertion hole 220, the second coupling protrusion 120 may be pressed in the upper-lower direction Z.

Accordingly, the end portion 121 facing in the forward direction X may be provided to be bent in the upper-lower direction Z as shown in FIG. 12. Since the second coupling protrusion 120 may not be inserted into the second insertion hole 220 while the end portion 122 of the first coupling protrusion 120 is arranged outside the second insertion hole 220 in the forward X, the second coupling protrusion 120 is inserted into the second insertion hole 220, and then the second coupling protrusion 120 is pressed such that the end portion 122 is disposed outside the second insertion hole 220.

Although few embodiments of the disclosure have been shown and described, the above embodiment is illustrative purpose only, and it would be appreciated by those skilled in the art that changes and modifications may be made in these embodiments without departing from the principles and scope of the disclosure, the scope of which is defined in the claims and their equivalents.

What is claimed is:

1. A display apparatus comprising:
a display panel on which a screen is displayable along a first direction;
a light source module including a plurality of light sources configured to emit light toward the display panel, the plurality of light sources being spaced apart from each other along a second direction perpendicular to the first direction;
a rear chassis, to support the light source module, which is arrangeable at a rear side of the display panel, the rear chassis including a plurality of coupling protrusions spaced apart from each other along the second direction; and
a heat dissipation member, coupleable to the rear chassis, and configured to dissipate heat generated from the light source module, the heat dissipation member including a plurality of insertion holes into which the plurality of coupling protrusions of the rear chassis are insertable, the plurality of insertion holes being spaced apart from each other along a long axis of the heat dissipation member which extends along the second direction,
wherein a first insertion hole, among the plurality of insertion holes, is at a center along the long axis, and a second insertion hole, among the plurality of insertion holes, is adjacent to a side end of the heat dissipation member along the long axis and in a shape elongated along the long axis.

2. The display apparatus of claim 1, wherein the heat dissipation member is formed of a material having greater thermal expansion than the rear chassis.

3. The display apparatus of claim 1, wherein a first coupling protrusion, among the plurality of coupling protrusions, is insertable into the first insertion hole and a second coupling protrusion, among the plurality of coupling protrusions, is insertable into the second insertion hole, and
a width of the second coupling protrusion along the second direction is smaller than a width of the second insertion hole along the second direction.

4. The display apparatus of claim 3, wherein
while the second coupling protrusion is inserted in the second insertion hole, the second coupling protrusion is configured to be movable along the second direction within the second insertion hole.

5. The display apparatus of claim 1, wherein
a first coupling protrusion, among the plurality of coupling protrusions, is insertable into the first insertion hole and a second coupling protrusion, among the plurality of coupling protrusions, insertable into the second insertion hole, and
the second coupling protrusion is in a hook shape bent along a third direction perpendicular to the first direction and the second direction.

6. The display apparatus of claim 5, wherein the second coupling protrusion includes a bent portion at which the second coupling protrusion extending along the first direction is bent toward the third direction and an end portion extending along the third direction from the bent portion, and
the end portion is disposed outside the second insertion hole along the third direction.

7. The display apparatus of claim 6, wherein
an area between a base of the second coupling protrusion and the bent portion in the first direction is configured not to be in contact with the heat dissipation member.

8. The display apparatus of claim 6, wherein the end portion of the display apparatus is configured to be in contact with the heat dissipation member.

9. The display apparatus of claim 1, wherein a first coupling protrusion, among the plurality of coupling protrusions, is insertable into the first insertion hole and a second coupling protrusion, among the plurality of coupling protrusions, is insertable into the second insertion hole, and
the first coupling protrusion is configured to be supported on the first insertion hole without a gap.

10. The display apparatus of claim 1, wherein a first coupling protrusion, among the plurality of coupling protrusions, is insertable into the first insertion hole and a second coupling protrusion, among the plurality of coupling protrusions, is insertable into the second insertion hole, and
the first coupling protrusion is in a tubular shape protruding along the first direction, and
an end portion of the first coupling protrusion in the first direction is bent to face toward the heat dissipation member.

11. The display apparatus of claim 10, wherein the end portion of the first coupling protrusion is bent along a third direction perpendicular to the first direction and the second direction to be in contact with the heat dissipation member.

12. The display apparatus of claim 1, wherein a first coupling protrusion, among the plurality of coupling protrusions, is insertable into the first insertion hole and a second coupling protrusion, among the plurality of coupling protrusions, is insertable into the second insertion hole,
the first coupling protrusion is in a tubular shape protruding along the first direction, and
an end portion of the first coupling protrusion along the first direction is configured to be in contact with the heat dissipation member.

13. The display apparatus of claim 1, wherein a first coupling protrusion, among the plurality of coupling protrusions, is insertable into the first insertion hole and a second coupling protrusion, among the plurality of coupling protrusions, is insertable into the second insertion hole, and
the first coupling protrusion is configured to be inserted into the first insertion hole without a gap.

14. The display apparatus of claim 1, wherein a first coupling protrusion, among the plurality of coupling protrusions, is insertable into the first insertion hole and a second coupling protrusion, among the plurality of coupling protrusions, is insertable into the second insertion hole, and
the first coupling protrusion is configured to be fixed to the first insertion hole, and the second coupling protrusion is supported to be movable in the second direction inside the second insertion hole.

15. The display apparatus of claim 1, wherein the first insertion hole is among a plurality of first insertion holes, and the second insertion hole is among a plurality of second insertion holes,, and
a number of the plurality of first insertion holes is greater than a number of the plurality of second insertion holes.
